(19) United States
(12) Patent Application Publication
(10) Pub. No.: US 2026/0312570 A1
(43) Pub. Date: Oct. 8, 2026

(54) SYSTEM AND METHOD FOR FINE TUNED PULSE WIDTH MODULATION SIGNAL GENERATION

(71) Applicant: Keithley Instruments, LLC, Solon, OH (US)

(72) Inventors: Ozgur Bolat, Streetsboro, OH (US); Daniel Mesenger, Reminderville, OH (US)

(21) Appl. No.: 19/633,851

(22) Filed: Mar. 30, 2026

Related U.S. Application Data
(60) Provisional application No. 63/783,571, filed on Apr. 4, 2025.

(51) Int. Cl. H03K 3/017; H03K 3/313

(52) U.S. Cl. CPC H03K 3/017; H03K 3/313

(57) ABSTRACT

A fine-control pulse-width modulated signal generator includes a preliminary pulse-width modulated signal generator structured to generate a base pulse-width modulated signal from a clock signal, a slew rate controller structured to modify an edge of the base pulse-width modulated signal, and a comparator having a first input that accepts an output of the slew rate controller and a second input that accepts a comparison threshold, the comparator structured to output a fine-control pulse-width modulated signal based on a comparison between the first input and the second input. The fine-control pulse-width modulated signal may be used by a switching power supply to finely control an output voltage of the power supply. Methods are also described.

### CROSS-REFERENCE TO RELATED APPLICATIONS

This disclosure is a non-provisional of and claims benefit from U.S. Provisional Application No. 63/783,571, titled “PULSE WIDTH MODULATION SIGNAL GENERATION USING FIELD PROGRAMMABLE GATE ARRAYS AND DIGITAL-TO-ANALOG CONVERTERS FOR 1MHZ,” filed on Apr. 4, 2025, the disclosure of which is incorporated herein by reference in its entirety.

### TECHNICAL FIELD

This disclosure relates to signal generating systems, and, more particularly, to systems that generate pulse-width modulation signals having user-specified qualities.

### BACKGROUND

Modern power supply modules allow the user to control an output signal voltage level. In Direct Current (DC) power supplies, the final output signal is typically a signal having a constant, DC output voltage. It is important that the output voltage be stable, i.e. the output voltage remains relatively constant, within a small tolerance, over time. It is also important that the user be able to precisely control the output voltage level of the power supply to meet the desired application.

Power supplies use different types of circuits to generate the output voltage signal depending on their design. Discrete linear regulated power supplies may be used to generate signals that satisfy both the output tolerance and fine control requirements described above. But, especially when used in larger power supplies, discrete linear regulators may be too large to physically fit within some design constraints. When small physical size is important, switching power supplies are oftentimes used. Generally, in a switching power supply, such as a buck converter, a Pulse-Width-Modulated (PWM) signal is used to control a solid state switch, such as a Metal Oxide Semiconductor Field Effect Transistor (MOSFET) switch in a voltage generating circuit. The MOSFET switch is very small. When the PWM signal that controls the MOSFET has a low duty cycle, the MOSFET switch is OFF longer than it is ON, which causes the output voltage of the voltage generating circuit to be relatively low. Conversely, when the PWM signal has a higher duty cycle, the output of the voltage generating circuit will likewise be higher.

When using a Field Programmable Gate Array (FPGA) in a circuit design, the circuit design choices may be limited by constraints of operating the FPGA fabric. For example, Phase-Locked Loops (PLLs) may be implemented in an FPGA to generate clock signals higher than a native frequency at which the FPGA operates. Limitations of the FPGA fabric, however, may prevent PWM generators from using such PLLs to accurately control the PWM generators at these higher frequencies.

Using standard PWM generators in an FPGA presents problems with being able to precisely control the PWM duty cycle. Recall from above that one of the important factors in power supply design is allowing the user to finely control the final output voltage from the power supply by adjusting the duty cycle of the PWM signal. As described above, modifying the duty cycle of the PWM signal causes the switching power supply to increase or reduce the final output voltage of the power supply.

As mentioned above, FPGA fabrics typically have a maximum clock rate at which they can operate without experiencing errors. For example, an FPGA may have a maximum main or master clock frequency of approximately 100 MHz, which translates to a 10 ns clock cycle. If the desired PWM signal generated by the FPGA has a frequency of approximately 1 MHz, this translates to a 1000 ns clock cycle. Recall from above that fine control of the desired output voltage is important. Using the above clock cycles as an example, generating a PWM by modulating a 1000 ns clock cycle when the FPGA fabric limits the minimum amount of change in the PWM to 10 ns results in a PWM that can only vary by 1%, which is relatively large. This limit in resolution of the clock signal caused by the maximum clock speed in an FPGA directly limits the ability of the user to precisely control the duty cycle of the PWM implemented using FPGAs. And not being able to finely control the duty cycle of the PWM limits the amount of fine control that the user has in specifying the ultimate output voltage from the power supply.

### BRIEF DESCRIPTION OF THE DRAWINGS

FIG. 1 is a functional block diagram of a Pulse Width Modulation (PWM) signal generator according to embodiments of the disclosure.

FIG. 2 is a graph illustrating various output voltages of various portions of the PWM signal generator of FIG. 1, according to embodiments of the disclosure.

FIG. 3A is an example down slew rate controller element of the PWM signal generator of FIG. 1, according to embodiments.

FIG. 3B is another example down slew rate controller element of the PWM signal generator of FIG. 1, according to embodiments.

FIG. 3C is a yet another example down slew rate controller element of the PWM signal generator of FIG. 1, according to embodiments.

FIG. 4 is a schematic block diagram of a comparator used, in some embodiments, in the duty cycle controller component of the PWM signal generator of FIG. 1.

FIG. 5 is a schematic block diagram of an example voltage generator including some or all of the components of the PWM signal generator of FIG. 1, according to embodiments.

FIG. 6 is a flowchart illustrating example operations used to generate a controllable PWM signal according to embodiments.

### DESCRIPTION

Embodiments of the disclosure include integrating field programmable gate array (FPGA) control with a digital-to-analog converter (DAC) to generate pulse-width modulation (PWM) signals with sub-1 ns resolution at a frequency of 1 MHz. Other embodiments include a finely tunable PWM signal generator from a clock generator that has less than 1% fine control.

The present disclosure involves generating a PWM control signal that is finely tunable. The PWM signal may be used to control a MOSFET in a synchronous switching power supply, such as a buck converter. In embodiments, the duty cycle of the PWM signal directly correlates with the output of the buck converter. Therefore, higher resolution in the PWM control signal allows for more precise control of the output of the buck converter.

In some embodiments, a master clock is generated at 100 MHz or 125 MHz by an FPGA. Clock signals operating at a faster rate may encounter propagation delay issues due to the FPGA fabric. For example, if the FPGA generates a 100MHz clock, but is limited to only 10 ns variability in its clock signal, the overall resolution of the clock signal generated by the FPGA is limited to 1% clock variability in the clock signal.

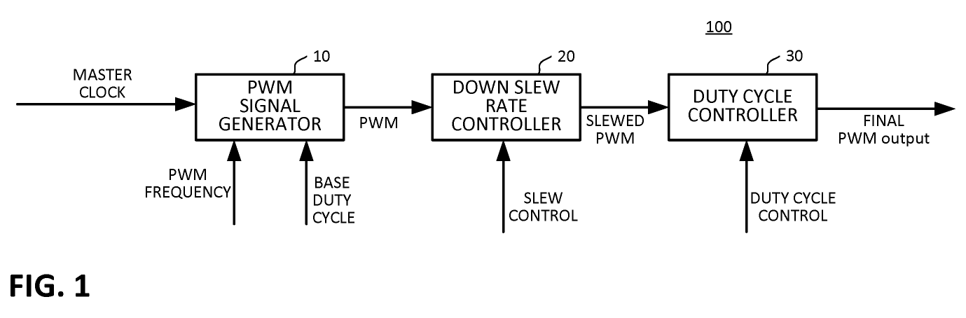

To achieve finer resolution, the present disclosure involves modifying a PWM signal generated, which may also be generated by the FPGA, to produce a finely controllable PWM signal using additional circuitry. The FPGA generates the PWM signal from a master clock, described in detail below. With reference to FIG. 1, a PWM generator 100 is illustrated that includes a PWM signal generator 10, a slew rate controller 20, and a duty cycle controller 30. As described in further detail below, the PWM signal generator 10 accepts a master clock signal, such as a 100 MHz clock signal generated by an FPGA, and outputs a PWM signal with a predetermined duty cycle, and adjustable by 1% accuracy. Other inputs to the PWM signal generator 10 include a desired PWM frequency and a base, or gross duty cycle. The PWM signal output from the PWM signal generator 10 may be produced from the master clock signal based on the overall design, such as the FPGA master clock. In one embodiment the PWM signal generator 10 produces a 25 MHz PWM signal from the 100 MHz master clock signal. The output of the PWM signal generator 10 may be referred to as a PWM signal having a selectable base duty cycle, although the base duty cycle is limited by the master clock signal.

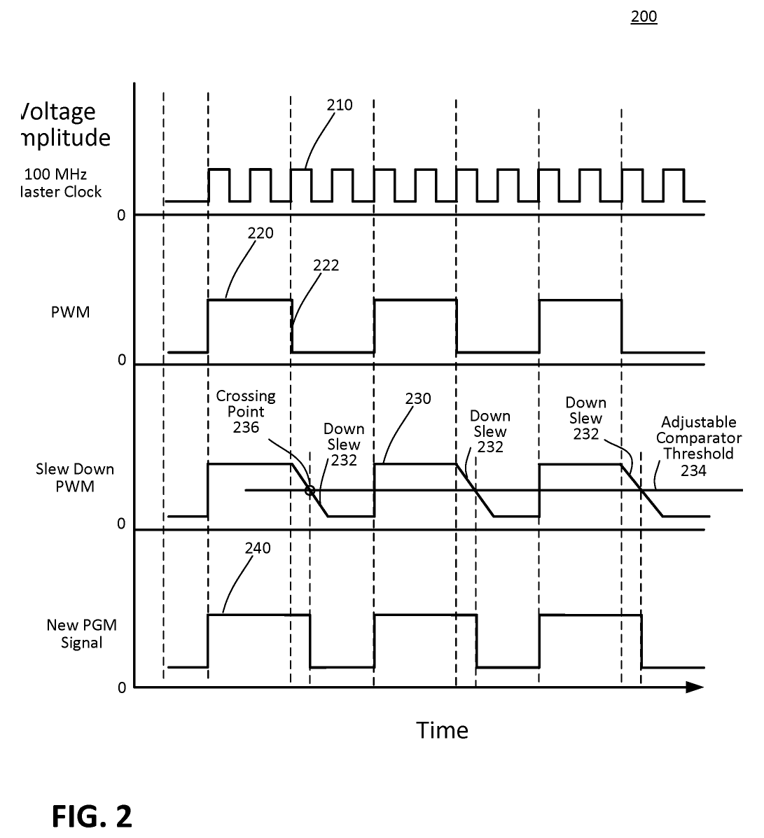

The slew rate controller 20 includes circuitry, or circuit functions, that control one of the edges of the PWM signal output from the PWM signal generator 10. The functions of the slew rate controller 20 may be controlled through a control line, pictured in FIG. 1. With reference to FIG. 2, an original master clock signal is illustrated as 210. In this embodiment, the master clock signal 210 has a frequency of 100 MHz and may be generated by an FPGA. In other embodiments the master clock signal may be generated by another clock source. No matter how it is produced, the master clock signal 210 may be an example clock signal that is presented to the PWM signal generator 10 of FIG. 1.

The PWM signal generator 10 uses the master clock signal 210 to generate a PWM signal 220 having a desired frequency. In the illustrated embodiment, the PWM signal 220 has a frequency of 25 MHz and has a 50% duty cycle. Compared to the master clock signal 210, the PWM signal 220 stays HIGH for two full cycles of the master clock signal 210 and then transitions to LOW for two additional cycles of the master clock.

With reference back to FIG. 1, the slew rate controller 20 uses various circuitry to modify the PWM signal 220. Ultimately, as described below, modifying the PWM signal 220 provides an ability to more finely tune the duty cycle of the desired PWM than is available from the PWM signal generator 10, since the PWM signal generator 10 is limited to 1% accuracy. Referring back to FIG. 2, an example output of the slew rate controller 20 (FIG. 1) is illustrated as slew down PWM signal 230. Comparing the slew down PWM signal 230 to the PWM signal 220 in FIG. 2, the difference between these signals is based on differences in the falling edge of the two PWM signals. The original PWM signal 220 includes a falling edge 222 that falls immediately, or very quickly, between the HIGH value and the LOW value of the PWM signal 220. With reference to the slew down PWM signal 230, a falling edge 232 takes much longer to transition from the HIGH value of the slew down PWM signal 230 to the LOW value of the slew down PWM signal 230. This rate of falling of the PWM signal 230 is referred to as the slew rate, which is the change in output value of the signal, such as the slew down PWM signal 230, over the time takes to completely change values from HIGH to LOW. The falling edge portion 222 of the PWM signal 220 has a very fast, or immediate slew rate, while the falling edge portion 232 of the slew down PWM signal 230 has a lower slew rate. Generally, although not required, the slew rate of the falling edge 232 is controlled by the slew rate controller 20 (FIG. 1) to complete its transition from HIGH to LOW prior to the next rising edge of the PWM signal 220.

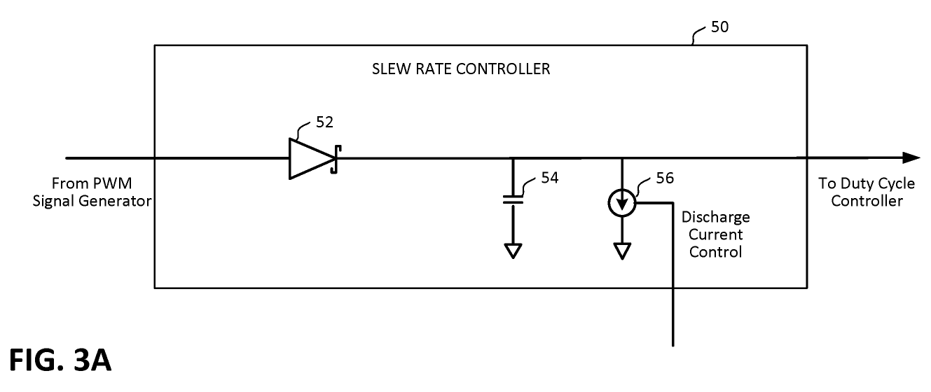

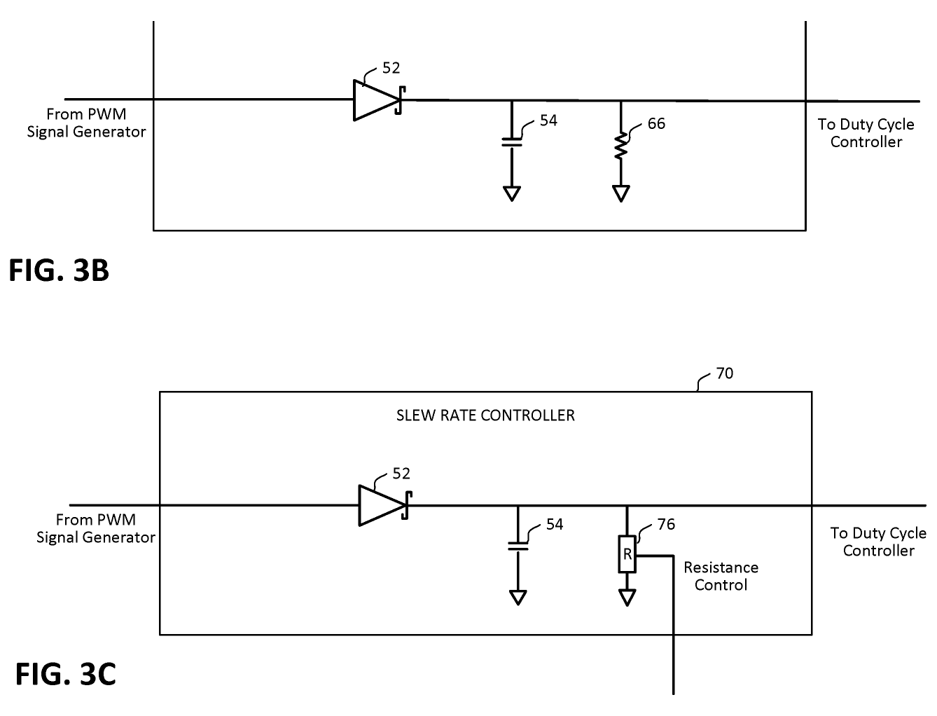

Depending on the embodiment, different circuits may be used within the slew rate controller 20 (FIG. 1) to control the slew rate of the falling edge 232 of the slew down PWM signal 230. With reference to FIG. 3A, a slew rate controller 50 may be an example of the slew rate controller 20 of FIG. 1. The slew rate controller 50 includes a diode 52, which may be a Schottky diode, coupled to a capacitor 54 and a current sink, or current generator 56. The current generator 56, when turned on, provides a path between a capacitor 54, which is coupled to the output of the slew rate controller 50, and a ground reference.

The input to the slew rate controller 50 is the output of the PWM signal generator 10 (FIG. 1), an example of which is illustrated as the PWM signal 220 in FIG. 2. The slew rate controller 50 causes the falling edge 232 of the PWM signal 230 to fall more slowly, or has a lower slew rate, than the falling edge 222 of the PWM signal 220. In more detail, when the PWM signal 220 is in its HIGH state, the capacitor 54 charges with energy provided by the HIGH state signal. Then, when the PWM signal 220 would otherwise fall immediately to its LOW state, such as illustrated in FIG. 2, the slew rate controller 50 delays or slows the transition time between the HIGH state and the LOW state, thus increasing the slew time, and decreasing the slew rate of the falling edge 232. In practice, when the PWM signal 220 input to the slew rate controller 50 transitions from HIGH to LOW, the current generator 56 provides a path to the ground reference. Controlling the operation of the current generator 56 controls how quickly the energy stored in the capacitor 54 is discharged to the ground reference. The diode 52, being a one-way device, prevents the energy stored in the capacitor 54 from being discharged back through the diode. Instead, the capacitor 54 discharges through the current generator 56, at a controllable rate, until it is completely discharged, and the falling edge 232 of the slew down PWM signal 230 reaches its LOW state. This controlled discharge of the capacitor 54 is illustrated in FIG. 2 by the down slew, or falling edge portion 232, of the slew down PWM signal 230.

With reference back to FIG. 3A, the size of the capacitor 54, the level to which the capacitor 54 is charged, and a rate of discharge of the current generator 56 controls the slew rate of the falling edge 232 of the slew down PWM signal 230. For example, increasing the rate at which the current generator 56 sinks current to the ground reference from the capacitor 54 causes the falling edge 232 to fall faster from the HIGH state to the LOW state, while decreasing the rate at which the current generator 56 sinks the current to the ground reference causes the falling edge 232 to fall slower. Thus, embodiments of the disclosure can control the slew rate of the PWM signal in real time by controlling the operation of the current generator 56.

In addition to using a current generator 56 to control the slew rate, such as found within the slew rate controller 50 of FIG. 3A, other forms of slew rate control may be used. For example, FIG. 3B illustrates a slew rate controller 60 where the current generator 56 of FIG. 3A has been replaced with a single resistor 66. The other circuit components of the slew rate controller 60 are unchanged from the slew rate controller 50, the functions of which are not repeated for brevity. In the slew rate controller 60 of FIG. 3B, when the PWM signal 220 falls from its HIGH state to its LOW state, the energy is discharged from the capacitor 54 through a resistor 66 to the ground reference. One difference between slew rate controller 60 of FIG. 3B and the slew rate controller 50 of FIG. 3A is that the resistor 66 is static, meaning that the rate at which the capacitor 54 discharges to the ground reference is dependent on the resistive-capacitive (RC) network of the resistor 66 and capacitor 54. Although not illustrated, discharging a capacitor, such as the capacitor 54 through a fixed RC network follows a non-linear path, where the energy discharges more quickly just after the PWM signal 220 transitions from HIGH to LOW, when the capacitor 54 is being rapidly discharged, compared to the later portions, as the capacitor 54 is being further discharged. Thus, compared to the slew down PWM signal 230 of FIG. 3A, using a slew rate controller 60 of FIG. 3B, with the fixed RC network, would cause the down edge portion 232 to have a curved, or backwards-J shape, compared to the relatively linear shape of the falling edge 232 of the slew down PWM signal 230 when the slew rate controller 50 (FIG. 3A) is used.

FIG. 3C illustrates yet another slew rate controller 70, which is similar to the slew rate controller 60 of FIG. 3B, except that the slew rate controller 70 includes a controllable resistance 76. In this embodiment, the resistance of the controllable resistance 76 may be modified, or changed, during the down slew portion when the PWM signal 220 transitions from HIGH to LOW. This controllable resistance allows the system to control the rate at which the down edge portion 232 of the slew down PWM signal 230, modifying the parameters of the RC network formed by the resistance 76 and capacitor 54, which modifies the shape of the discharge curve compared to the output of the slew rate controller 60. Similar to controlling the current generator 56 in the slew rate controller 50 of FIG. 3A, the resistance 76 may be controlled in the slew rate controller 70 of FIG. 3C in real time.

Although illustrated embodiments of the disclosure have described modifying the falling edge of the PWM signal 220, it is possible to modify the rising edge of the PWM signal 220 to control the overall output of the finely controlled new PWM signal. In other embodiments it is possible to modify both the rising edge and the falling edge of the PWM signal 220.

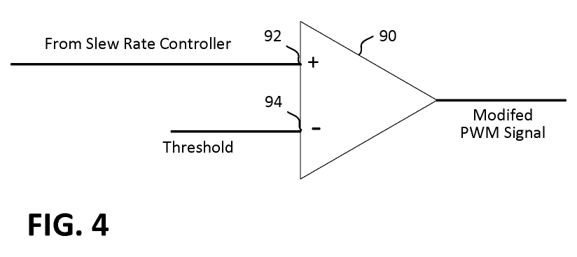

With reference back to FIG. 1, recall that the output of the down slew rate controller 20 is passed to the duty cycle controller 30 to generate the final PWM signal having a controllable duty cycle. In some embodiments, the duty cycle controller 30 includes a comparator, such as a comparator 90 illustrated in FIG. 4. The comparator 90 includes a non-inverting input 92 and an inverting input 94. In the illustrated embodiment, the non-inverting input 92 is coupled to the output of the slew rate controller 20 (FIG. 1), while the inverting input 94 receives a threshold value which is used by the comparator 90. Modifying the threshold value to the comparator 90 causes the output of the comparator to control the duty cycle of the new PWM signal, as will be discussed with reference to FIG. 2. The threshold value may be one example of the duty cycle control coupled to the duty cycle controller 30, illustrated in FIG. 1.

FIG. 2 illustrates a new PWM signal 240, which, in some embodiments, reflects the output of the comparator 90 of FIG. 4.

With reference to FIG. 4, by comparing the new PWM signal 240 to the PWM signal 220, it can be seen that the new PWM signal 240 has a larger duty cycle than the original PWM signal 220. Also note that the falling edge of the new PWM signal 240 coincides with a crossing point 236 on the slewed down PWM signal 230, which marks where the falling edge portion 232 of the slew down PWM signal 230 crosses an adjustable comparator threshold 234. Thus, adjusting the level of the adjustable comparator threshold 234 controls where the falling edge of the new PWM signal 240 will be placed in time. And controlling the time at which the falling edge of the new PWM signal 240 falls thereby adjusts the duty cycle of the new PWM signal 240. In other words, controlling the threshold value of the comparator 90 of FIG. 4 adjusts the duty cycle of the new PWM signal 240. And, more specifically, in the illustrated embodiments, raising the threshold value of the comparator 90 decreases the duty cycle of the new PWM signal 240, while lowering the threshold value of the comparator 90 increases the duty cycle. Note also that, in this embodiment, the rising edge of the new PWM signal 240 always aligns with the rising edge of the original PWM signal 220. The threshold value coupled to the inverting input 94 of the comparator 90 may be an example of the duty cycle control that is coupled to the duty cycle controller 30, illustrated in FIG. 1.

Thus, the duty cycle of the new PWM signal 240 may be specified by controlling the slew rate of the falling edge portion 232 of the slew down PWM signal 230. The duty cycle of the new PWM signal 240 may also be further specified by controlling the threshold value of a comparator 90 (FIG. 4) in the duty cycle controller 30 (FIG. 1). As described below, in some embodiments only one of these values need be controlled to modify the duty cycle of the new PWM 240, while in other embodiments, both elements of control, and/or others, may be used. In general, modifying the slew rate of the slew down PWM signal 230 provides a relatively larger change in the duty cycle of the new PWM signal 240 than does changing the threshold value of the comparator 90. But, as stated above, either or both of the controls may be used to produce the new PWM signal 240 having the desired, final, duty cycle.

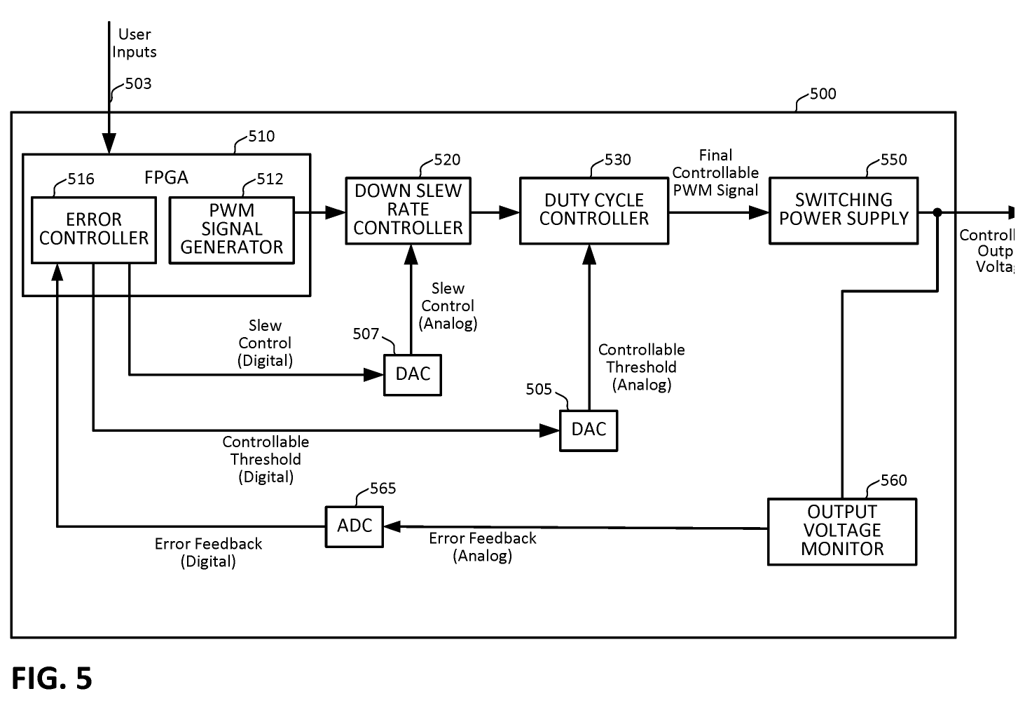

FIG. 5 is a schematic block diagram of a voltage generator 500 including some or all of the components of the PWM signal generator of FIG. 1, according to embodiments. In the illustrated embodiment, an FPGA 510 generates a master clock signal, which is used by a PWM signal generator 512 to generate a base PWM signal. In the illustrated environment, the PWM signal generator 512 is shown as being embodied within the FPGA 510 itself, but in other embodiments the PWM signal generator 512 may be external to the FPGA. The PWM signal generator 512 may be an embodiment of the PWM signal generator 10 of FIG. 1. As described above, the PWM signal generator 512 generates the PWM signal based on the master clock signal, such as the master clock signal of the FPGA 510. But recall from above, that the PWM signal generator 512 can control the duty cycle of the PWM signal only in relatively large steps, based on the master clock frequency. In the example above, the PWM signal generator 512 is only able to control the output PWM signal to a resolution of 1%. Using additional components, as described herein, embodiments of the disclosure are able to achieve much greater precision in a final PWM signal than is available by merely manipulating a master clock signal.

Next, the PWM signal from the PWM signal generator 512 is fed to a slew rate controller 520, which may be an embodiment of the slew rate controller 20 of FIG. 1. As described above, the slew rate controller 20 may control the leading edge or the falling edge of the PWM signal, but, in the illustrated embodiments, the slew rate controller 520 controls the falling edge of the PWM signal and is therefore referred to as a down slew rate controller. Next the PWM signal having the slewed falling edge output of the slew rate controller 520 is presented to a duty cycle controller 530, which may be an embodiment of the duty cycle controller 30 of FIG. 1. In some embodiments the duty cycle controller 530 may include a comparator, such as the comparator 90 of FIG. 4, although other circuits may instead provide the duty cycle control function. Output from a Digital to Analog Converter (DAC) 505, and a DAC 507, which are described in more detail below, may provide feedback control to the down slew rate controller 520 and the duty cycle controller 530 during operation.

The output of the duty cycle controller 530 is the final, finely controllable PWM signal having a specified duty cycle according to embodiments of the disclosure. This final, new PWM signal, such as the new PWM signal 240 of FIG. 2, is presented to a switching power supply 550, which may be a buck converter to generate a final output voltage. As described above, the switching power supply generates a final, controllable output voltage that is determined by the duty cycle of a PWM signal that drives a MOSFET within the switching power supply 550. Thus, by adjusting the duty cycle of the PWM signal driving the switching power supply 550, the final output voltage from the switching power supply 550, and thus the final output voltage from the voltage generator 500, may be controlled to a very fine degree.

In some embodiments the final output voltage from the switching power supply 550 is coupled back to an output voltage monitor 560, which generates a signal based on the difference between a desired output voltage from the voltage generator 500 and the actual output voltage. In some embodiments this is referred to as an error signal, which may be fed back to an error controller 516 within the FPGA 510. In some embodiments, the error signal, in analog form, is converted to a digital signal through an Analog to Digital Converter (ADC) 565, which is passed back to the error controller 516 of the FPGA 510. In the illustrated embodiment the function of the error controller 516 is illustrated as being embodied by the FPGA 510, although in other embodiments the error controller may be separate from the FPGA. By providing feedback from the output voltage monitor 560, the digital error signal from the ADC 565 forms a measurement feedback control loop through which the error controller 516 can modify the operation of other components of the voltage generator 500 to generate the final output voltage with high precision.

The error controller 516 may generate a slew control signal to actively control the slew rate controller 520 to control the shape of the modified PWM signal output from the slew rate controller. In the illustrated embodiment, the error controller 516 produces a digital slew rate control, which is converted to an analog slew rate control by the DAC 507. Then the analog slew rate control is fed to the slew rate controller 520 to actively control the slew rate, as described above with reference to FIGS. 3A and 3C. As stated above, the slew rate control may control the rate of discharge of the current generator 56 (FIG. 3A) or modify the controllable resistance 76 (FIG. 3B). In other embodiments of the slew rate controller 520, the slew rate control may control other aspects of the slew rate controller 520.

Further, the error controller 516 may use the error signal from the output voltage monitor 560 as data source to control the DAC 505 to adjust the controllable threshold applied to the duty cycle controller 530 as detailed above. As described with reference to the DAC 507, the output from the error controller 516 may be a digital signal representing the threshold that is then converted to an analog threshold signal by the DAC 505, before applying the analog threshold signal to the duty cycle controller 530, which, in some embodiments, is a comparator. In some embodiments the reference voltage output by the DAC 505 increases or decreases the threshold voltage applied to the comparator by linear steps, while in other embodiments, the reference voltage output of the DAC 505 uses logarithmic increases or decreases to control the threshold voltage. This novel approach of controlling either or both of the down slew rate controller 520 and the duty cycle controller 530 enhances the precision for generating PWM signals in embodiments according to the disclosure.

In some embodiments, more or fewer of the components illustrated separately in FIG. 5 may be physically embodied in the FPGA 510 itself. For example, either or both of the down slew rate controller 520 and duty cycle controller 530 may be embodied with the FPGA 510. And in other embodiments the DACs 505, 507 may also be part of the FPGA 510 as well, depending on implementation details. Similarly, although the PWM signal generator 512 is shown as being implemented within the FPGA 510, it may be a stand-alone or separate from the FPGA.

Further, in the illustrated embodiment, the FPGA 510 includes one or more user inputs 503 through which the desired output of the voltage generator 500 may be specified. The user input may be controlled by a menu on the voltage generator 500 itself, or specified in another way, such as an input made by a controlling computer.

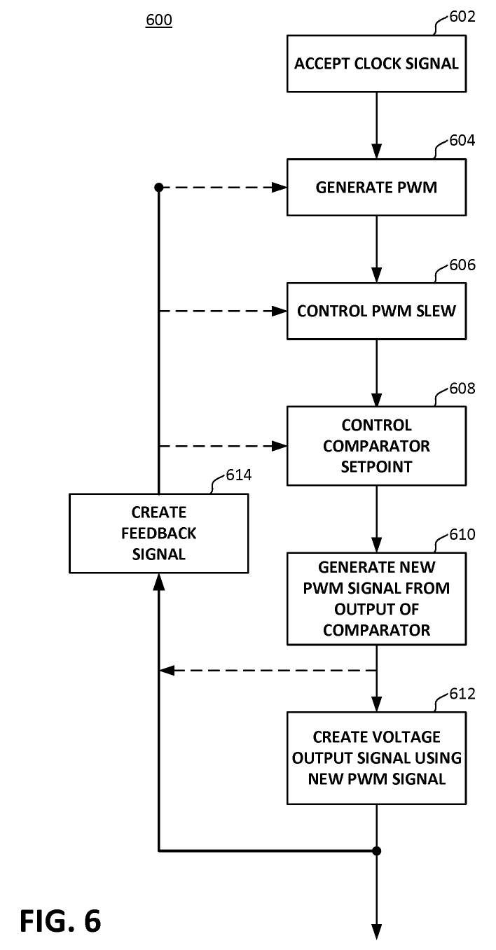

FIG. 6 is a flowchart illustrating example operations in a flow 600 used to generate a controllable PWM signal according to embodiments. The flow 600 begins by accepting a clock signal in an operation 602. As described above, the clock signal may be a master clock originating in an FPGA, or the clock signal may be generated using other circuitry.

An operation 604 generates the base PWM signal from the master clock signal. This function may be performed by, for example, the PWM signal generator 512 of FIG. 5. Next, in an operation 606, the slew of the generated PWM signal is controlled. For example, one of the falling or rising edges of the PWM signal, or both, is modified though a slew modifier, as detailed above. In the above description, the falling edge of the rescaled clock signal was controlled through a slew rate controller 20, which could take various forms, such as those illustrated in FIGS. 3A, 3B or 3C, although other embodiments are also possible without deviating from the spirit of the invention herein. Controlling the slew rate of the falling edge of the PWM signal elongates the time of the transition between the HIGH state of the PWM signal and the LOW state of the PWM signal. The slew rate can be controlled through a variety of methods, described above, which yields different shapes and durations of skew.

An operation 608 generates a comparison setpoint that is used in the following operation. In some embodiments the setpoint may start from a set initial value, which may be modified during operation of the flow 600, as described further below.

Next, in an operation 610, a duty cycle controller generates a new PWM signal from the PWM signal having the modified slew, as described above. In one embodiment, a comparator evaluates a level of the instantaneous modified PWM signal against the threshold value set in the operation 608, and the output of the comparator becomes the new PWM signal having a modified duty cycle, as described above.

Finally, an operation 612 applies the new PWM signal from the duty cycle controller, such as the comparator 90 of FIG. 4, to a switching power supply, such as a buck converter. The output of the switching power supply becomes the output voltage desired by, and set by, the user.

A feedback signal may be generated in an operation 614 from either the new PWM signal output by the duty cycle controller in the operation 610, or from the final output voltage signal from the switching power supply in the operation 612. In whatever form, the feedback signal generated in 614 is based on a comparison of the desired signal to the actual, instantaneous signal. Then, the flow 600 uses the feedback signal to control circuits or systems in the power generation circuit as described above. The feedback may be used to control the original PWM signal created in the operation 604. For example, in the described embodiment the clock signal from operation 602 was scaled down to a clock signal having 25% of the original clock rate. But, using the feedback signal from the operation 614, the scaled clock rate could be scaled to a different value. And, although described above and illustrated in FIG. 2 as the PWM signal 220 having a 50% duty cycle, another base duty cycle may be chosen for the base PWM signal.

Alternatively, or in addition, the feedback signal of operation 614 could be used to control the slew rate of the slew rate controller, such as the slew rate controller 20 of FIG. 1, that produced the PWM slew in operation 606. Modifying the slew rate may take various forms, such as increasing or reducing the rate of change of a linear slew of a falling edge of the PWM signal, or increasing or reducing the rate of a non-linear slew. Modifying the slew rate in various ways was described with reference to FIGS. 3A, 3B, and 3C above.

Still further, alternatively, or in addition to both uses of the feedback signal described above, the feedback signal from operation 614 may be used to modify the threshold value set in operation 608 that is used by the duty cycle controller in operation 610 to create the final, modified PWM signal. The feedback from operation 614 to operations 604, 606, 608 is shown in dashed lines to indicate that any or all of these feedback mechanisms may be used, in any combination, to modify the final PWM signal, and, by extension, the final output voltage signal to the final output voltage signal specified by the user as described above. Although not typical, it is possible that the original duty cycle of the final PWM exactly matches the desired duty cycle, and no adjustments based on the feedback signal of operation 614 need be used.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

### EXAMPLES

Illustrative examples of the disclosed technologies are provided below. An embodiment of the technologies may include one or more, and any combination of, the examples described below.

Example 1 is a fine-control pulse-width modulated signal generator that may include a preliminary pulse-width modulated signal generator structured to generate a base pulse-width modulated signal from a clock signal, a slew rate controller structured to modify an edge of the base pulse-width modulated signal, and a comparator having a first input that accepts an output of the slew rate controller and a second input that accepts a comparison threshold, the comparator structured to output a fine-control pulse-width modulated signal based on a comparison between the first input and the second input.

Example 2 is the signal generator according to Example 1, in which the slew rate controller is actively controlled.

Example 3 is the signal generator according to Example 1 or Example 2, in which the slew rate controller includes a controllable current sink.

Example 4 is the signal generator according to any one of Examples 1-3, in which the slew rate controller includes a resistive-capacitive network.

Example 5 is the signal generator according to any one of Examples 1-4, in which a resistance in the resistive-capacitive network is controllable.

Example 6 is the signal generator according to any one of Examples 1-5, in which the comparator threshold applied to the second input is controllable.

Example 7 is the signal generator according to any one of Examples 1-6, in which the preliminary pulse-width modulated signal generator is embodied in a field programmable gate array.

Example 8 is the signal generator according to any one of Examples 1-7 in which the clock signal is a master clock signal of the field programmable gate array.

Example 9 is a power supply that may include: a pulse-width signal generator having a preliminary pulse-width modulated signal generating circuit structured to generate a base pulse-width modulated signal from a clock, a slew rate controller structured to modify an edge of the base pulse-width modulated signal, and a comparator having a first input that accepts an output of the slew rate controller, and a second input that accepts a comparison threshold, the comparator structured to output a second pulse-width modulated signal based on a comparison between the first input and the second input, and a switching power supply coupled to the output of the comparator and structured to generate an output voltage of the power supply.

Example 10 the power supply according to Example 9, in which the switching power supply includes a switching transistor that is controlled by the second pulse-width modulated signal output by the comparator.

Example 11 is the power supply according to Example 9 or Example 10, which may further include an error correction circuit coupled to the output voltage of the power supply and structured to generate an error signal that indicates a difference between the output voltage of the power supply and a desired output voltage of the power supply.

Example 12 is the power supply according to any one of Examples 9-11, in which the error correction circuit is coupled to a controller in the power supply.

Example 13 is the power supply according to any one of Examples 9-12 in which the controller is structured to modify operation of one or more of the slew rate controller and the comparison threshold.

Example 14 is the power supply according to any one of Examples 9-13 in which either or both of the preliminary pulse-width modulated signal generating circuit and the controller are part of a field programmable gate array.

Example 15 is a method of generating a refined pulse-width modulated signal, which may include generating a base pulse-width modulated signal, controlling a slew rate of an edge of the base pulse-width modulated signal to generate a modified pulse-width modulated signal, comparing the modified pulse-width modulated signal to a threshold value, and outputting the refined pulse-width modulated signal based on the comparison of the modified pulse-width modulated signal to the threshold value.

Example 16 is the method according to Example 15, which may further include generating a feedback signal that compares the modified pulse-width modulated signal to a desired pulse-width modulated signal.

Example 17 is the method according to Example 15 or Example 16, which may further include modifying the slew rate of the edge of the base pulse-width modulated signal using the feedback signal.

Example 18 is the method according to any one of Examples 15-17, which may further include modifying the threshold value based on the feedback signal.

Example 19 is the method according to any one of Examples 15-18, which may further include accepting a clock signal from a field-programmable gate array, and in which generating a base pulse-width modulated signal comprises generating a base pulse-width modulated signal from the clock signal.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

We claim:

1. A fine-control pulse-width modulated signal generator, comprising:
a preliminary pulse-width modulated signal generator structured to generate a base pulse-width modulated signal from a clock signal;
a slew rate controller structured to modify an edge of the base pulse-width modulated signal; and
a comparator having a first input that accepts an output of the slew rate controller and a second input that accepts a comparison threshold, the comparator structured to output a fine-control pulse-width modulated signal based on a comparison between the first input and the second input.

2. The signal generator according to claim 1, in which the slew rate controller is actively controlled.

3. The signal generator according to claim 2, in which the slew rate controller includes a controllable current sink.

4. The signal generator according to claim 1, in which the slew rate controller includes a resistive-capacitive network.

5. The signal generator according to claim 4, in which a resistance in the resistive-capacitive network is controllable.

6. The signal generator according to claim 1, in which the comparator threshold applied to the second input is controllable.

7. The signal generator according to claim 1, in which the preliminary pulse-width modulated signal generator is embodied in a field programmable gate array.

8. The signal generator according to claim 7 in which the clock signal is a master clock signal of the field programmable gate array.

9. A power supply, comprising:
a pulse-width signal generator, including:
a preliminary pulse-width modulated signal generating circuit structured to generate a base pulse-width modulated signal from a clock signal,
a slew rate controller structured to modify an edge of the base pulse-width modulated signal, and
a comparator having a first input that accepts an output of the slew rate controller and a second input that accepts a comparison threshold, the comparator structured to output a second pulse-width modulated signal based on a comparison between the first input and the second input; and
a switching power supply coupled to the output of the comparator and structured to generate an output voltage of the power supply.

10. The power supply according to claim 9, in which the switching power supply includes a switching transistor that is controlled by the second pulse-width modulated signal output by the comparator.

11. The power supply according to claim 9, further comprising an error correction circuit coupled to the output voltage of the power supply and structured to generate an error signal that indicates a difference between the output voltage of the power supply and a desired output voltage of the power supply.

12. The power supply according to claim 11, in which the error correction circuit is coupled to a controller in the power supply.

13. The power supply according to claim 12 in which the controller is structured to modify operation of one or more of the slew rate controller and the comparison threshold.

14. The power supply according to claim 12 in which either or both of the preliminary pulse-width modulated signal generating circuit and the controller are part of a field programmable gate array.

15. A method of generating a refined pulse-width modulated signal, comprising:
generating a base pulse-width modulated signal;
controlling a slew rate of an edge of the base pulse-width modulated signal to generate a modified pulse-width modulated signal;
comparing the modified pulse-width modulated signal to a threshold value; and
outputting the refined pulse-width modulated signal based on the comparison of the modified pulse-width modulated signal to the threshold value.

16. The method according to claim 15, further comprising generating a feedback signal that compares the modified pulse-width modulated signal to a desired pulse-width modulated signal.

17. The method according to claim 16, further comprising modifying the slew rate of the edge of the base pulse-width modulated signal using the feedback signal.

18. The method according to claim 16, further comprising modifying the threshold value based on the feedback signal.

19. The method according to claim 15, further comprising accepting a clock signal from a field-programmable gate array, and in which generating a base pulse-width modulated signal comprises generating a base pulse-width modulated signal from the clock signal.
